(19) United States
(12) Patent Application Publication
(10) Pub. No.: US 2013/0001565 A1
(43) Pub. Date: Jan. 3, 2013

(54) DISPLAY DEVICES AND METHODS OF MANUFACTURING DISPLAY DEVICES

(76) Inventors: Sung-Woo Jung, Yongin-city (KR); Hyun-Chul Kim, Yongin-city (KR); Deok-Hoi Kim, Yongin-city (KR); Chung Yi, Yongin-city (KR)

(21) Appl. No.: 13/326,637

(22) Filed: Dec. 15, 2011

(30) Foreign Application Priority Data
Jul. 1, 2011 (KR) 10-2011-0065339

(51) Int. Cl. H01L 51/50; H01L 51/40

(52) U.S. Cl. 257/59; 438/34; 257/E51.001; 257/E51.018; 257/40

(57) ABSTRACT

A display device includes a gate line, a switching device, a first electrode, an organic light emitting structure and a second electrode. The gate line may include a first conductive layer pattern and a second conductive layer pattern. The first conductive layer pattern may extend along a first direction and the second conductive layer pattern may extend along a second direction. The switching device may be connected to the gate line. The first electrode may be electrically connected to the switching device. The organic light emitting structure may be disposed on the first electrode. The second electrode may be disposed on the organic light emitting structure.

### CROSS-REFERENCE TO RELATED APPLICATION

This application claims priority under 35 U.S.C. §119 to and the benefit of Korean patent Application No. 2011-0065339, filed on Jul. 1, 2011, the disclosure of which is hereby incorporated by reference herein in its entirety.

### BACKGROUND

1. Field

Example embodiments of the invention relate to display devices and methods of manufacturing display devices. More particularly, example embodiments of the invention relate to display devices including switching devices having improved electrical characteristics and methods of manufacturing display devices including switching devices having improved electrical characteristics.

2. Description of Related Art

Generally, a switching device used in display devices may be formed on a transparent substrate including glass, quartz, etc. A channel region of the switching device may include polysilicon formed by a process of crystallizing amorphous silicon. Particularly, when the switching device is formed on a glass substrate having a relatively low melting temperature, the crystallization process may need to be performed at a relatively low temperature.

A crystallization process for forming polysilicon from amorphous silicon may include methods using heat energy such as solid phase crystallization, metal induced crystallization, and metal induced lateral crystallization and methods using a laser such as excimer laser crystallization and sequential lateral solidification. In the solid state crystallization method, a heat treatment process may be performed on amorphous silicon at temperatures below about 700° C. for hours, thereby forming polysilicon. According to the excimer laser crystallization, an excimer laser may be irradiated onto the amorphous silicon layer in a short period of time, so that the irradiated portion of the amorphous silicon layer may be highly heated to form polysilicon. In accordance with the metal induced crystallization, a metal may be in contact with amorphous silicon or may be injected into the amorphous silicon so that, the phase change from amorphous silicon to polysilicon may be induced. In the metal induced lateral crystallization, a metal silicide generated by a reaction of metal and amorphous silicon may spread laterally, thereby inducing the crystallization of the amorphous silicon.

In the sequential lateral solidification method, the crystallization may be preceded sequentially from a side of the amorphous silicon film by using a high energy laser. A grain size, a grain shape, and a grain arrangement of polysilicon may be controlled by the sequential lateral solidification method. However, when a transistor having a bottom gate structure is formed by using the sequential lateral solidification, a heat loss may occur through the gate under the amorphous silicon, so that the amorphous silicon may not be crystallized to uniform polysilicon. When the transistor includes a channel region having non-uniform polysilicon, the electrical property of the transistor may be largely deteriorated.

### SUMMARY

Aspects of example embodiments are directed toward display devices including a transistor having a uniformly crystallized active pattern and improved electrical characteristics.

Aspects of example embodiments are directed toward methods of manufacturing display devices including a transistor having a uniformly crystallized active pattern and improved electrical characteristics.

According to example embodiments, there is provided a display device including a gate line, a switching device (e.g., a transistor), a first electrode, an organic light emitting structure, and a second electrode. The gate line may include a first conductive layer pattern and a second conductive layer pattern. The first conductive layer pattern may extend along a first direction, and the second conductive layer pattern may extend along a second direction. The switching device may be connected to the gate line. The first electrode may be electrically connected to the switching device. The organic light emitting structure may be disposed on the first electrode. The second electrode may be disposed on the organic light emitting structure.

In example embodiments, the second conductive layer pattern may cover the first conductive layer pattern, and a gate electrode of the switching device may be connected to the second conductive layer pattern.

In example embodiments, the first conductive layer pattern may include aluminum (Al), silver (Ag), platinum (Pt) and/or alloys thereof.

In example embodiments, the second conductive layer pattern may include molybdenum (Mo), titanium (Ti), chromium (Cr), tantalum (Ta) and/or alloys thereof.

In example embodiments, the gate electrode may be formed together with the second conductive layer pattern.

In example embodiments, the gate electrode may have a thickness identical to that of the second conductive layer pattern.

In example embodiments, the first conductive layer pattern may have a thickness substantially larger than that of the gate electrode or that of the second conductive layer pattern.

In example embodiments, the second conductive layer pattern may be disposed on the first conductive layer pattern, and a gate electrode of the switching device may be connected to the first conductive layer pattern.

In example embodiments, the gate electrode may be formed together with the first conductive layer pattern.

In example embodiments, each of the first conductive layer pattern and the gate electrode may include silicon doped with impurities.

In example embodiments, the second conductive layer pattern may include aluminum (Al), silver (Ag), platinum (Pt) and/or alloys thereof.

In example embodiments, the gate electrode may have a thickness identical to (the same as) that of the second conductive layer pattern. The first conductive layer pattern may have a thickness substantially larger than that of the gate electrode or that of the second conductive layer pattern.

In example embodiments, there is provided a method of manufacturing a display device. In the method, a gate line may be formed on a substrate. The gate line may include a first conductive layer pattern and a second conductive layer pattern. The first conductive layer pattern may extend along a first direction, and the second conductive layer pattern may extend along a second direction. A switching device may be formed over the substrate. The switching device may include a gate electrode. The gate electrode may contact the gate line. A first electrode may be electrically connected to the switching device. An organic light emitting structure may be formed on the first electrode. A second electrode may be formed on the organic light emitting structure.

In example embodiments, forming of the gate line may include forming the first conductive layer pattern on the substrate, and forming the second conductive layer pattern to enclose the first conductive layer pattern.

In example embodiments, forming of the gate line may include forming the first conductive layer pattern on the substrate and forming the second conductive layer pattern to cover the first conductive layer pattern.

In example embodiments, the second conductive layer pattern and the gate electrode may be formed concurrently or simultaneously.

In example embodiments, the forming of the gate line may include forming the first conductive layer pattern on the substrate and forming the second conductive layer pattern on the first conductive layer pattern.

In example embodiments, the first conductive layer pattern and the gate electrode may be formed concurrently or simultaneously.

In example embodiments, forming of the switching device may include forming a gate insulation layer on the substrate to cover the gate electrode, forming a semiconductor layer on the gate insulation layer, the semiconductor layer including amorphous silicon, and crystallizing the semiconductor layer using an excimer laser.

In example embodiments, crystallizing of the semiconductor layer may further include heating the substrate and the gate electrode.

In example embodiments, heating of the substrate and the gate electrode may include irradiating an infrared ray onto the substrate.

In example embodiments, the heating of the substrate and the gate electrode may include disposing the substrate on a chuck capable of controlling temperature.

In example embodiments, the heating of the substrate and the gate electrode may include applying a current to the gate electrode.

According to example embodiments, a gate electrode may have a relatively thin thickness, so that a heat loss through the gate electrode may be reduced in a crystallization process for forming an active pattern. Therefore, a semiconductor layer may be effectively and uniformly crystallized. Further, a conductive layer pattern of a gate line may have a relatively large thickness and may include a material having a relatively low electrical resistance, so that an increase of a gate resistance due to a thickness reduction in the gate electrode may be compensated. As a result, electrical characteristics of a switching device including the gate electrode and the active pattern may be improved.

### BRIEF DESCRIPTION OF THE DRAWINGS

Example embodiments may be understood in more detail from the following description taken in conjunction with the accompanying drawings, in which:

FIG. 1 is a plan view illustrating a display device in accordance with example embodiments;

FIG. 2 is a cross sectional view illustrating the display device taken along a line I-II in FIG. 1;

FIG. 3 is a cross sectional view illustrating the display device taken along a line III-IV in FIG. 1;

FIGS. 4 to 12 are cross sectional views illustrating a method of manufacturing a display device in accordance with example embodiments;

FIG. 13 is a cross sectional view illustrating a display device in accordance with some example embodiments;

FIGS. 14 to 16 are cross sectional views illustrating a method of manufacturing a display device in accordance with some example embodiments;

FIG. 17 is a cross sectional view illustrating a method of manufacturing a display device in accordance with some example embodiments;

FIG. 18 is a cross sectional view illustrating a method of manufacturing a display device in accordance with some example embodiments; and

FIG. 19 is a cross sectional view illustrating a method of manufacturing a display device in accordance with some example embodiments.

### DETAILED DESCRIPTION

Various example embodiments will be described more fully hereinafter with reference to the accompanying drawings, in which some example embodiments are shown. The invention may, however, be embodied in many different forms and should not be construed as limited to the example embodiments set forth herein. Rather, these example embodiments are provided so that this description will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer; or one or more intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, fourth etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

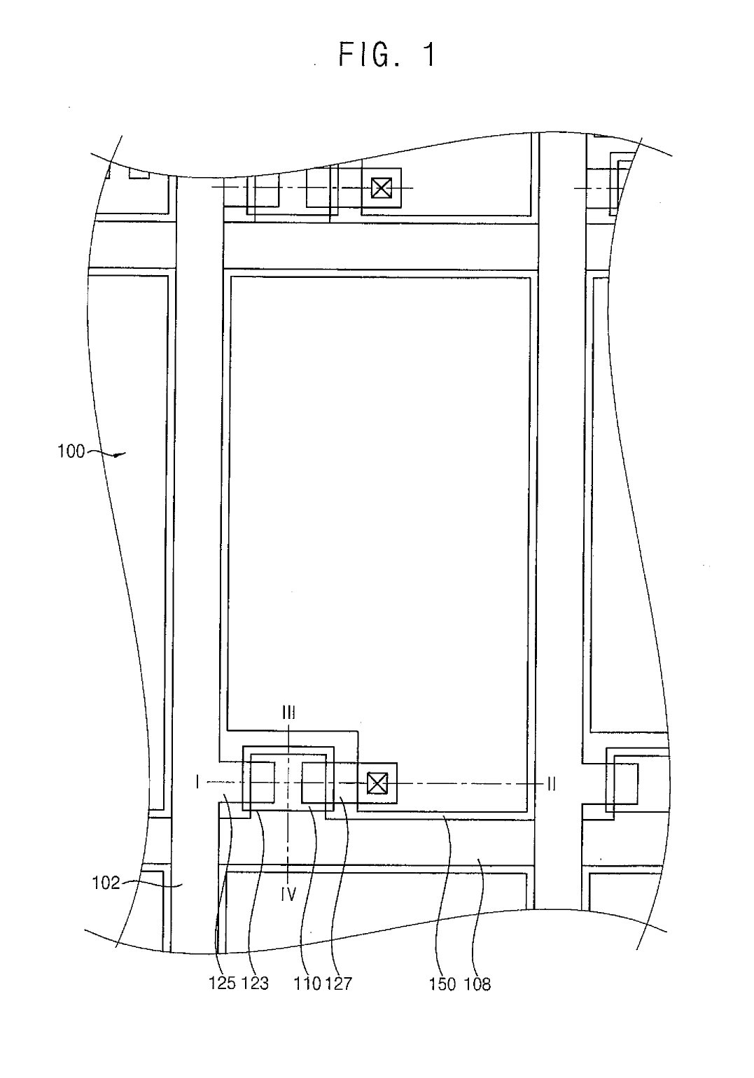

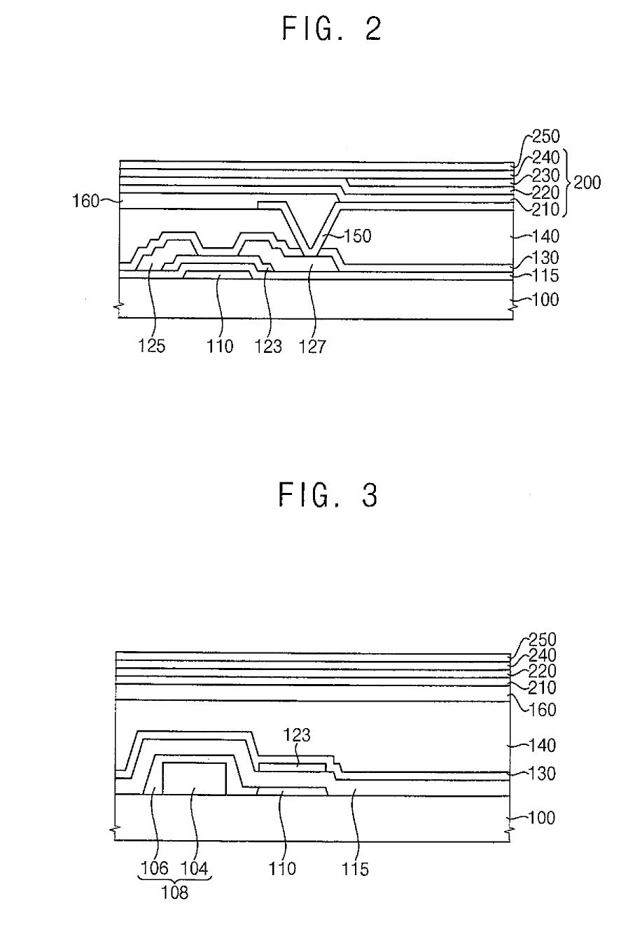

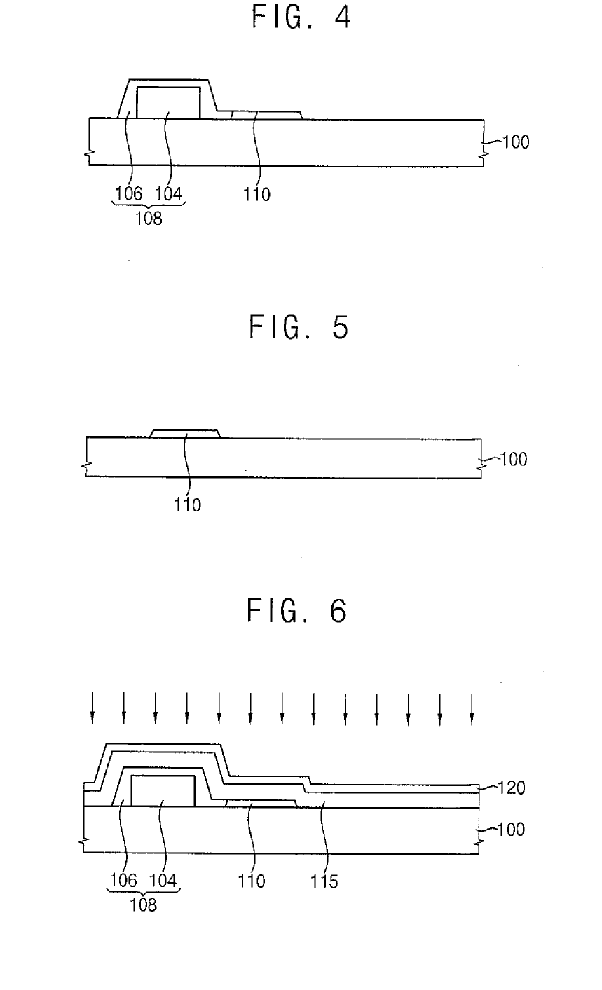

FIG. 1 is a plan view illustrating a display device in accordance with example embodiments. FIG. 2 is a cross sectional view illustrating the display device taken along a line I-II in FIG. 1. FIG. 3 is a cross sectional view illustrating the display device taken along a line III-IV in FIG. 1.

Referring to FIG. 1, the display device may include a gate line 108 and a data line 102 disposed on a substrate 100. In example embodiments, each gate line 108 may extend along a first direction on the substrate 100. Further, a plurality of gate lines 108 may be arranged substantially parallel to one another. Each data line 102 may extend along a second direction on the substrate 100. In this case, the first direction may be substantially perpendicular to the second direction. That is, a plurality of data lines 102 may be arranged substantially perpendicular to the gate lines 108, respectively. However, the first direction and the second direction may be referred to or arranged in the alternate. For example, the gate line 108 may extend along the second direction, and the data line 102 may extend along the first direction. A pixel region of the display device may be defined by the gate line 108 and the data line 102.

Referring to FIGS. 1 and 2, the display device may include a switching device (e.g., a transistor) which is disposed in the pixel region defined by the gate line 108 and the data line 102. The display device may further include an organic light emitting structure 200, a first electrode 150 and a second electrode 250, which may be disposed in the pixel region. By applying a current through the first electrode 150 or the second electrode 250, the organic light emitting structure 200 may generate a set or predetermined color of light. Hereinafter, a region where the switching device may be disposed in the pixel region of the display device may be referred to as a “device region.”

As illustrated in FIGS. 1 and 3, the display device may include the substrate 100, a switching device disposed on the substrate 100, the first electrode 150, the organic light emitting structure 200, the second electrode 250, etc. The gate line 108 and the data line 102 disposed on the substrate 100 may be substantially perpendicular to each other to thereby define the pixel region.

The data line 102 may include metal, alloy, metal nitride, conductive metal oxide, etc. For example, the data line 102 may include aluminum (Al), tungsten (W), copper (Cu), nickel (Ni), chromium (Cr), molybdenum (Mo), titanium (Ti), platinum (Pt), silver (Ag), tantalum (Ta), ruthenium (Ru), alloys thereof, nitrides thereof, indium tin oxide (ITO), indium zinc oxide (IZO), zinc tin oxide (ZTO), zinc oxide (ZnOx), tin oxide (SnOx) gallium oxide (GaOx), etc. These may be used alone or in a combination thereof.

In example embodiments, the gate line 108 may include a first conductive layer pattern 104 and a second conductive layer pattern 106. The first conductive layer pattern 104 may extend along the first direction on the substrate 100, and the second conductive layer pattern 106 may partially or fully cover the first conductive layer pattern 104. In this case, the second conductive layer pattern 106 may extend along the second direction. For example, the second conductive layer pattern 106 may fully cover an upper face and a side wall of the first conductive layer pattern 104. In some example embodiments, the second conductive layer pattern 106 may partially cover the first conductive layer pattern 104 and may extend along the second direction. In some example embodiments, the first conductive layer pattern 104 may extend along a direction substantially parallel to a direction of the data line 102, and the second conductive layer pattern 106 may extend along a direction substantially perpendicular to that of the first conductive layer pattern 104.

The second conductive layer pattern 106 may have a uniform thickness along a profile of the first conductive layer pattern 104. In this case, the first conductive layer pattern 104 may have a thickness substantially larger than that of the second conductive layer pattern 106. For example, the first conductive layer pattern 104 may have a thickness above about 200 nm from an upper face of the substrate 100.

In example embodiments, the first conductive layer pattern 104 may include metal or alloy having a relatively low electrical resistivity. For example, the first conductive layer pattern 104 may include aluminum (Al), platinum (Pt), silver (Ag), alloys of these metal etc. These may be used alone or in a combination thereof. In case the first conductive layer pattern 104 may have a relatively large thickness and a relatively low electrical resistance, a total resistance of the gate line 108 may be reduced by the first conductive layer pattern 104.

The second conductive layer pattern 106 may include a material capable of reducing a heat loss. For example, the second conductive layer pattern 106 may include molybdenum (Mo), titanium (Ti), chromium (Cr), tantalum (Ta), alloy thereof, etc. For example, the second conductive layer pattern 106 may have a relatively thin thickness below about 50 nm. Therefore, a thickness ratio between the first conductive layer pattern 104 and the second conductive layer pattern 106 may be about 4.0:1.0 or less. The gate line 108 includes the first and the second conductive layer patterns 104 and 106, so that the active pattern 123 may be uniformly crystallized by reducing a heat loss in formation of the active pattern 123 without increasing a size of the switching device. Accordingly, desired electrical characteristics such as improved charge mobility may be ensured.

Referring to FIGS. 1 and 3, the switching device of the display device may include a gate electrode 110, a gate insulation layer 115, the active pattern 123, a source electrode 125, a drain electrode 127, etc. A protection layer 130 may be disposed on the source and the drain electrodes 125 and 127 of the switching device and the active pattern 123.

The gate electrode 110 may be connected to the gate line 108. In example embodiments, the gate electrode 110 may be formed integrally with the second conductive layer pattern 106 of the gate line 108. In this case, the gate line 108 may have a substantially line shape or a substantially bar shape. The gate electrode 110 may be connected to the second conductive layer pattern 106 of the gate line 108. The gate electrode 110 may include metal, alloy, metal nitride, conductive metal oxide, etc. For example, the gate electrode 110 may include aluminum (Al), tungsten (W), copper (Cu), nickel (Ni), chromium (Cr), molybdenum (Mo), titanium (Ti), platinum (Pt), silver (Ag), tantalum (Ta), ruthenium (Ru), alloys thereof, nitrides thereof, indium tin oxide (ITO), indium zinc oxide (IZO), zinc tin oxide (ZTO), zinc oxide (ZnOx), tin oxide (SnOx) gallium oxide (GaOx), etc. These may be used alone or in a combination thereof. In example embodiments, the gate electrode 110 may include a material substantially the same as or substantially similar to that of the second conductive layer pattern 106. Further, the gate electrode 110 may have a relatively thin thickness below about 50 nm. A thickness ratio between the gate electrode 110 and the first conductive layer pattern 104 of the gate line 108 may be less than about 4.0:1.0. The gate electrode 110 may have a thickness substantially the same as or substantially similar to that of the second conductive layer pattern 106 of the gate line 108.

In some example embodiments, a buffer layer (not illustrated) may be disposed between the gate line 108 and the substrate 100 and between the gate electrode 110 and the substrate 100. The buffer layer may prevent or protect metal atoms and/or impurities from diffusing from the substrate 100. Further, the buffer layer may improve a flatness of an upper surface of the substrate 100. The buffer layer may include silicon compound. For example, the buffer layer may include silicon oxide (SiOx), silicon nitride (SiNx), silicon oxy-nitride (SiOxNy), silicon oxy-carbide (SiOxCy), silicon carbide nitride (SiCxNy), etc. These may be used alone or in a combination thereof. The buffer layer may have a single layer structure or a multi layer structure including a silicon compound film.

Referring to FIGS. 2 and 3, the gate insulating layer 115 may be disposed on the substrate 100 to cover the gate line 108 and the gate electrode 110. The gate insulation layer 115 may have a uniform thickness along a profile of the gate electrode 110. The gate insulation layer 115 may include silicon compound, metal oxide, etc. For example, the gate insulation layer 115 may include silicon oxide, silicon nitride, silicon oxy-nitride, hafnium oxide (HfOx), zirconium oxide (ZrOx), aluminum oxide (AlOx), tantalum oxide (TaOx), etc. These may be used alone or in a combination thereof. Further, the gate insulation layer 115 may have a single layer structure or a multi layer structure including a silicon compound film and/or a metal oxide film.

The active pattern 123 may be disposed on a portion of the gate insulation layer 115 under which the gate electrode 110 is located. The active pattern 123 may include silicon. For example, the active pattern 123 may include polysilicon, polysilicon doped with impurities, amorphous silicon, amorphous silicon doped with impurities, partially crystallized silicon, micro crystalline silicon, etc. In example embodiment, the active pattern 123 may include low temperature polysilicon (LTPS). The low temperature polysilicon may have high electron mobility and may be highly integrated, so that it may be advantageous in case a size of the pixel region of the display device is relatively small. When the active pattern 123 including low temperature polysilicon is formed, an amorphous silicon layer (not illustrated) may be formed on the gate insulation layer 115, and then the amorphous silicon layer may be crystallized using an excimer laser to form the active pattern 123. The crystallization process using the excimer laser will be described below in more detail.

In example embodiments, the gate line 108 including the second conductive layer pattern 106 and the gate electrode 110 may have a relatively thin thickness, so that a heat loss through the gate electrode 110 and the gate line 108 may be reduced or minimized in the formation of the active pattern 123 without increasing the size of the switching device. Accordingly, the active pattern 123 may include low temperature polysilicon having uniform and relatively large grain size, so that electrical characteristics of the switching device having the active pattern 123 may be improved.

The source electrode 125 and the drain electrode 127 may be disposed on the active pattern 123. In this case, the source electrode 125 may be connected to the data line 102. In example embodiments, the source electrode 125 may extend from the data line 102 having a substantially line shape or a substantially bar shape. The source electrode 125 and the drain electrode 127 may be located adjacent to the gate electrode 110. The source and the drain electrodes 125 and 127 may be spaced apart from each other. Each of the source electrode 125 and the drain electrode 127 may include metal, alloy, metal nitride, conductive metal oxide, etc. For example, the source electrode 125 and the drain electrode 127 may include aluminum (Al), tungsten (W), copper (Cu), nickel (Ni), chromium (Cr), molybdenum (Mo), titanium (Ti), platinum (Pt), silver (Ag), tantalum (Ta), ruthenium (Ru), alloys thereof, nitrides thereof, indium tin oxide (ITO), indium zinc oxide (IZO), zinc tin oxide (ZTO), zinc oxide (ZnOx), tin oxide (SnOx) gallium oxide (GaOx), etc. These may be used alone or in a combination thereof.

In some example embodiments, an ohmic contact pattern (not illustrated) may be respectively disposed between the source electrode 125 and active pattern 123 and between the drain electrode 127 and the active pattern 123. The ohmic contact patterns may include amorphous silicon highly doped with impurities. The ohmic contact patterns may reduce contact resistance between the source and drain electrodes 125 and 127 and the active pattern 123.

The protection layer 130 may be disposed on the gate insulation layer 115 to cover the source electrode 125, the drain electrode 127 and the active pattern 123. The protection layer 130 may have a uniform thickness along profiles of the source electrode 125, the drain electrode 127 and the active pattern 123. The protection layer 130 may include silicon compound. For example, the protection layer 130 may include silicon oxide (SiOx), silicon nitride (SiNx), silicon oxy-nitride (SiOxNy), silicon oxy-carbide (SiOxCy), silicon carbide nitride (SiCxNy), etc.

An insulation layer 140 may be disposed on the protection layer 130. The insulation layer 140 may include a transparent organic material. For example, the insulation layer 140 may include acryl-based resin, epoxy-based resin, phenol-based resin, polyamide-based resin, polyimide-based resin, unsaturated polyester-based resin, polyphenylene-based resin, polyphenylene sulfide-based resin, benzocyclobutene (BCB), etc. These may be used alone or in a combination thereof. The insulation layer 140 may have a substantially flat surface for elements of the display device which will be disposed thereon. Further, a first opening may pass through the insulation layer 140 and the protection layer 130 to partially expose the drain electrode 127.

Referring now to FIGS. 1 and 3, the first electrode 150 may be disposed on the insulation layer 140 in the pixel region. Depending on an emission type of the display device, the first electrode 150 may include a reflective material or a substantially transparent material. For example, when the display device is a bottom emission type, the first electrode 150 may include a transparent conductive material such as indium tin oxide, zinc tin oxide, indium zinc oxide, zinc oxide, tin oxide, gallium oxide, etc. These may be used alone or in a combination thereof. Further, the first electrode 150 may have a single layer structure or a multi layer structure including at least one transparent conductive material film. Alternatively, when the display device is a top emission type, the first electrode 150 may include a reflective material such as aluminum (Al), tungsten (W), copper (Cu), nickel (Ni), chromium (Cr), molybdenum (Mo), titanium (Ti), platinum (Pt), silver (Ag), tantalum (Ta), ruthenium (Ru), alloys thereof, nitrides thereof, etc. In this case, the first electrode 150 may have a single layer structure or a multi layer structure including a metal film, an alloy film and/or a metal nitride film.

A pixel defining layer 160 may be disposed on the insulation layer 140 and the first electrode 150 in the device region. The pixel defining layer 160 may include an organic material and/or an inorganic material. For example, the pixel defining layer 160 may include an organic material such as photoresist, polyacryl-based resin, polyimide-based resin, acryl-based resin, etc. The inorganic material in the pixel defining layer 160 may include silicon compound. The pixel defining layer 160 may define a display region generating light in the pixel region.

The organic light emitting structure 200 may be disposed on the pixel defining layer 160 and the first electrode 150. In example embodiments, the organic light emitting structure 200 may include a hole injection layer 210, a hole transfer layer 220, an organic light emitting layer 230, an electron transfer layer 240, etc. In this case, the hole injection layer 210 may be disposed on the first electrode 150 and the pixel defining layer 160. For example, the hole injection layer 210 may include cupper phthalocyanine (CuPc), poly(3,4)-ethylenedioxythiophene (PEDOT), polyaniline (PANI), N,N-dinaphthyl-N,N′-diphenyl benzidine (NPD), etc. The hole transfer layer 220 may be disposed on the hole injection layer 210. For example, the hole transfer layer 220 may include N,N-dinaphthyl-N,N′-diphenyl benzidine (NPD), N,N′-bis-(3-methylphenyl)-N,N′-bis-(phenyl)-benzidine (TPD), s-TAD, 4,4′,4″-Tris(N-3-methylphenyl-N-phenyl-amino)-triphenylamine (MTDATA), etc. The organic light emitting layer 230 may be located on the hole transfer layer 220 in the light emitting region. The organic light emitting layer 230 may include an organic material or a mixture of an organic material and an inorganic material generating at least one of a red color of light, a green color of light, and a blue color of light. In some example embodiments, the organic light emitting layer 230 include a stacked structure including light emitting layers for the red color of light, the green color of light, and the blue color of light to generate a white color of light. The electron transfer layer 240 may be disposed on the organic light emitting layer 230 and the hole transfer layer 220. For example, the electron transfer layer 240 may include Alq3 (tris(8-hydroxyquinolino)aluminum), PBD, TAZ, Spiro-PBD, BAIq, SAlq, etc.

The second electrode 250 may be disposed on the electron transfer layer 240. The second electrode 250 may include a reflective material or a substantially transparent material depending on the emission type of the display device.

When the display device is the bottom emission type, the second electrode 250 may have a reflective material such as aluminum (Al), tungsten (W), copper (Cu), nickel (Ni), chromium (Cr), molybdenum (Mo), titanium (Ti), platinum (Pt), silver (Ag), tantalum (Ta), ruthenium (Ru), alloys thereof, nitrides thereof, etc. These may be used alone or in a combination thereof. Alternatively, when the display device is the top emission type, the second electrode 250 may include a transparent conductive material such as indium tin oxide, zinc tin oxide, indium zinc oxide, zinc oxide, tin oxide, gallium oxide, etc. These may be used alone or in a combination thereof.

The display device may include a second substrate (not illustrated) disposed on the second electrode 250. In this case, the second substrate may include a glass substrate, a quartz substrate, a transparent resin substrate, a transparent ceramic substrate, etc.

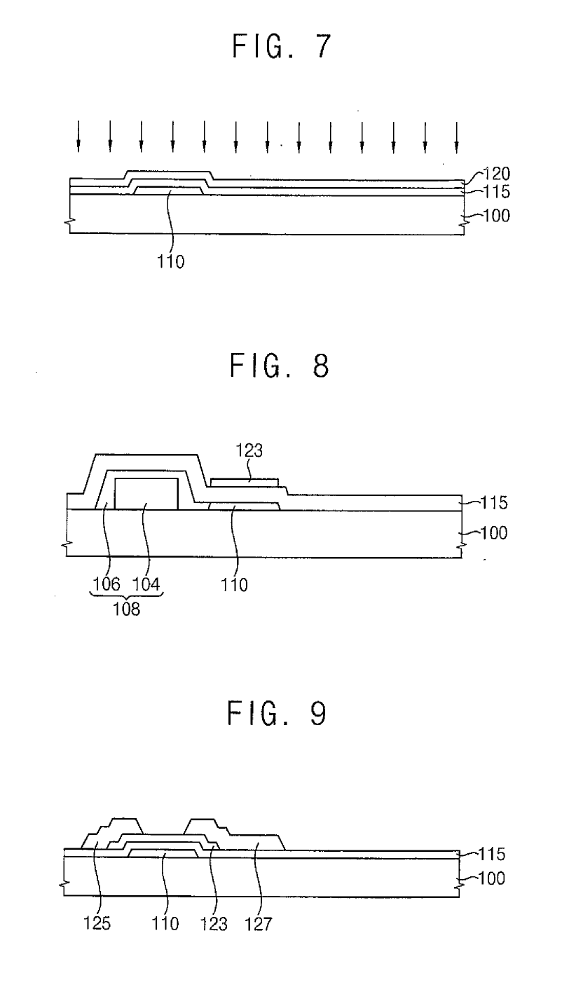

FIGS. 4 to 12 are cross sectional views illustrating a method of manufacturing a display device in accordance with example embodiments. In FIGS. 4 to 12, FIGS. 4, 6 and 8 are cross sectional views illustrating the method of manufacturing the display device having a construction substantially the same as or substantially similar to that of the display device taken along a line in FIG. 1. Additionally, FIGS. 5, 7, 9, 10, 11 and 12 are cross sectional views illustrating the method of manufacturing the display device having a construction substantially the same as or substantially similar to that of the display device taken along a line I-II in FIG. 1.

Referring to FIGS. 4 and 5, a gate line 108 and a gate electrode 110 may be formed on a substrate 100 including a glass substrate, a quartz substrate, a transparent resin substrate, a transparent ceramic substrate, etc.

In example embodiments, a first conductive layer (not illustrated) may be formed on the substrate 100. In this case, the first conductive layer may be formed by a sputtering process, a spray process, a chemical vapor deposition (CVD) process, an atomic layer deposition (ALD) process, a vacuum evaporation process, a printing process, etc. Further, the first conductive layer may be formed using metal, alloy, metal nitride, a transparent conductive material, etc. For example, the first conductive layer may be formed using aluminum (Al), tungsten (W), copper (Cu), nickel (Ni), chromium (Cr), molybdenum (Mo), titanium (Ti), platinum (Pt), silver (Ag), tantalum (Ta), ruthenium (Ru), alloys thereof, nitrides thereof, indium tin oxide (ITO), indium zinc oxide (IZO), zinc tin oxide (ZTO), zinc oxide (ZnOx), tin oxide (SnOx) gallium oxide (GaOx), etc. These may be used alone or in a combination thereof.

The first conductive layer may be patterned to form a first conductive layer pattern 104 on the substrate 100. The first conductive layer pattern 104 may extend along a first direction on the substrate 100. For example, the first conductive layer pattern 104 may have a relatively large thickness above about 200 nm, so that a resistance of the gate line 108 may be reduced. In example embodiments, the first conductive layer pattern 104 may be formed using aluminum (Al), platinum (Pt), silver (Ag) and/or alloys thereof, which may have a relatively low resistivity.

In example embodiments, a second conductive layer (not illustrated) may be formed on the substrate 100 to enclose the first conductive layer pattern 104. The second conductive layer may be formed by a sputtering process, a spray process, a chemical vapor deposition process, an atomic layer deposition process, an evaporation process, a printing process, etc. The second conductive layer may be formed using metal, alloy, metal nitride, a transparent conductive material, etc. For example, the second conductive layer may be formed using aluminum (Al), tungsten (W), copper (Cu), nickel (Ni), chromium (Cr), molybdenum (Mo), titanium (Ti), platinum (Pt), silver (Ag), tantalum (Ta), ruthenium (Ru), alloys thereof, nitrides thereof, indium tin oxide (ITO), indium zinc oxide (IZO), zinc tin oxide (ZTO), zinc oxide (ZnOx), tin oxide (SnOx) gallium oxide (GaOx), etc. The second conductive layer may have a uniform thickness along a profile of the first conductive layer pattern 104. The second conductive layer may be patterned to form a second conductive layer pattern 106 and a gate electrode 110 on the substrate 100. Accordingly, the gate line 108 including the first and the second conductive layer patterns 104 and 106 may be formed on the substrate 100 to contact the gate electrode 110.

The second conductive layer pattern 106 may cover an upper face and a side wall of the first conductive layer pattern 104. The second conductive layer pattern 106 may extend along a second direction substantially perpendicular to the first direction. In example embodiments, the gate electrode 110 may be connected to the second conductive layer pattern 106 of the gate line 108. In one embodiment, when the gate electrode 110 and the second conductive layer pattern 106 are formed concurrently or simultaneously, the gate electrode 110 is formed integrally with the second conductive layer pattern 106. In this case, each of the gate electrode 110 and the second conductive layer pattern 106 may have a relatively thin thickness. For example, each of the gate electrode 110 and the second conductive layer pattern 106 may have a thickness below about 50 nm. In example embodiments, the gate electrode 110 and the second conductive layer pattern 106 may be formed using molybdenum (Mo), titanium (Ti), chromium (Cr) and/or tantalum (Ta), which may have a relatively large heat capacity.

In some example embodiments, before forming the gate line 108 and the gate electrode 110, a buffer layer (not illustrated) may be formed on the substrate 100. The buffer layer may prevent or protect metal atoms and/or impurities from diffusing from the substrate 100. In a successive crystallization process for forming an active pattern 123, the buffer layer may adjust a thermal conductivity to obtain the active pattern 123 having a uniform grain size. Further, the buffer layer may improve a flatness of an upper face of the substrate 100. The buffer layer may be formed on the substrate 100 using silicon compound by a chemical vapor deposition process, a plasma enhanced chemical vapor deposition (PECVD) process, a thermal oxidation process, a low pressure chemical vapor deposition (LPCVD) process, etc. For example, the buffer layer may be formed using silicon oxide (SiOx), silicon nitride (SiNx), silicon oxy-nitride (SiOxNy), silicon oxy-carbide (SiOxCy), silicon carbide nitride (SiCxNy), etc. These may be used alone or in a combination thereof. The buffer layer may be formed to have a single layer structure or a multi layer structure including at least one silicon compound film.

Referring to FIGS. 6 and 7, a gate insulation layer 115 may be formed on the substrate 100 to cover the gate electrode 110 and the gate line 108. The gate insulation layer 115 may be formed by a chemical vapor deposition process, a thermal oxidation process, a plasma enhanced chemical vapor deposition process, a high density plasma-chemical vapor deposition (HDP-CVD) process, etc. The gate insulation layer 115 may be formed to have a uniform thickness along profiles of the gate electrode 110 and the gate line 108. The gate insulation layer 115 may be formed using silicon compound and/or metal compound. For example, the gate insulation layer may be formed using silicon oxide, silicon nitride, hafnium oxide, zirconium oxide, aluminum oxide, tantalum oxide, etc. These may be used alone or in a combination thereof. The gate insulation layer 115 may have a single layer structure or a multi layer structure.

A semiconductor layer 120 may be formed on the gate insulation layer 115. The semiconductor layer 120 may have a uniform thickness along a profile of the gate insulation layer 115. The semiconductor layer 120 may be formed by a spin coating process, a chemical vapor deposition process, a plasma enhanced chemical vapor deposition process, a high density plasma-chemical vapor deposition process, etc. Further, the semiconductor layer 120 may be formed using amorphous silicon, amorphous silicon including impurities, etc.

Referring to FIGS. 6 and 7, the semiconductor layer 120 may be crystallized by irradiating an excimer laser onto the substrate 100 having the semiconductor layer 200 as indicated using arrows. In the crystallization process using the excimer laser, by melting a portion or all portions of the semiconductor layer 120 including the amorphous silicon, and by crystallizing the amorphous silicon, the semiconductor layer 120 may be crystallized into polysilicon. A pulsed laser having a set or predetermined oscillation frequency may be used as the excimer laser. Further, the excimer laser may be generated using krypton fluoride (KrF), xenon fluoride (XeF), xenon chloride (XeCI), etc.

In example embodiments, after irradiating the excimer laser onto a first portion of the semiconductor layer 120, the excimer laser may be irradiated onto a second portion of the semiconductor layer 120 substantially overlapped with the first portion. For example, the size of the overlapped portion may be in a range of about 80% to about 100% of the first portion size or the second portion size. By repeating the excimer laser irradiation process, the semiconductor layer 120 may be crystallized successively along a direction substantially parallel to the substrate 100.

In example embodiments, the gate electrode 110 may have a relatively thin thickness and may include a material having a relatively large heat capacity, so that a heat loss through the gate electrode 110 may be reduced or minimized. Therefore, the semiconductor layer 120 may be effectively crystallized. Further, the first conductive layer pattern 104 may have a relatively large thickness and may include a material having a relatively low electrical resistivity, so that an increase of a gate resistance due to a thickness reduction in the gate electrode 110 may be compensated.

Referring to FIGS. 8 and 9, the crystallized semiconductor layer 120 may be patterned to form the active pattern 123. As illustrated in FIG. 8, the active pattern 123 may be located on the gate electrode 110 by interposing the gate insulation layer 115 therebetween. As described above, the heat loss may be reduced or minimized during the crystallization process of the semiconductor layer 120, so that the active pattern 123 including polysilicon or polysilicon doped with impurities may be uniformly crystallized. Therefore, electrical characteristics of the switching device having the active pattern 123 may be improved.

In example embodiments, a third conductive layer (not illustrated) may be formed on the gate insulation layer 115 to cover the active pattern 123. The third conductive layer may be formed by a sputtering process, a spray process, a chemical vapor deposition process, an atomic layer deposition process, a vacuum evaporation process, a printing process, etc. The third conductive layer may be formed using metal, alloy, metal nitride, a transparent conductive material, etc. For example, the third conductive layer may be formed using aluminum (Al), tungsten (W), copper (Cu), nickel (Ni), chromium (Cr), molybdenum (Mo), titanium (Ti), platinum (Pt), silver (Ag), tantalum (Ta), ruthenium (Ru), alloys thereof, nitrides thereof, indium tin oxide (ITO), indium zinc oxide (IZO), zinc tin oxide (ZTO), zinc oxide (ZnOx), tin oxide (SnOx) gallium oxide (GaOx), etc. These may be used alone or in a combination thereof. The third conductive layer may be patterned to form a source electrode 125 and a drain electrode 127 on the active pattern 123 and the gate insulation layer 115. The source electrode 125 and the drain electrode 127 may be spaced apart from each other, so that active pattern 123 between the source electrode 125 and the drain electrode 127 may be partially exposed.

In some example embodiments, ohmic contact patterns (not illustrated) may be formed between the source electrode 125 and the active pattern 123 and between the drain electrode 127 and the active pattern 123. The ohmic contact patterns may be formed using amorphous silicon highly doped with impurities. The ohmic contact patterns may reduce a contact resistance between the source and drain electrodes 125 and 127 and the active pattern 123.

Referring to FIG. 10, a protection layer 130 may be formed on the source electrode 125, the drain electrode 127, the active pattern 123 and the gate insulation layer 115. The protection layer 130 may have a uniform thickness along profiles of the source electrode 125, the drain electrode 127, the active pattern 123 and the gate insulation layer 115. The protection layer 130 may be formed using silicon oxide (SiOx), silicon nitride (SiNx), silicon oxy-nitride (SiOxNy), silicon oxy-carbide (SiOxCy), silicon carbide nitride (SiCxNy), etc.

An insulation layer 140 may be formed on the protection layer 130. The insulation layer 140 may have enough thickness to protect from or prevent a coupling effect among the electrodes 110, 125 and 127 of the switching device a first electrode 150 and a second electrode 250 (see FIGS. 11 and 12). The insulation layer 140 may be formed on the protection layer 130 using an organic insulation material by a spray process, a vacuum evaporation process, a printing process, a spin coating process, etc. For example, the insulation layer 140 may be formed using acryl-based resin, epoxy-based resin, phenol-based resin, polyamide-based resin, polyimide-based resin, unsaturated polyester-based resin, polyphenylene-based resin, polyphenylene sulfide-based resin, benzocyclobutene (BCB), etc. They may be used alone or in a combination thereof. The insulation layer 140 may have a substantially level upper surface. For example, the upper surface of the insulation layer 140 may be planarized by a chemical mechanical polishing (CMP) process and/or an etch-back process. In some example embodiments, the insulation layer 140 may be formed using a material having a self-planarizing property.

The insulation layer 140 and the protection layer 130 may be partially etched to form a first opening partially exposing the drain electrode 127. For example, the first opening of the insulation layer 140 may be formed by a photolithography process.

Referring to FIG. 11, a forth conductive layer (not illustrated) may be formed on the insulation layer 140 to partially fill the first opening of the insulation layer 140. The forth conductive layer may be patterned to form the first electrode 150 on the insulation layer 140. Therefore, the first electrode 150 may be electrically connected to the drain electrode 127. In this case, the forth conductive layer may be formed on the insulation layer 140 by a sputtering process, a printing process, a spray process, a chemical vapor deposition process, an atomic layer deposition process, a vacuum evaporation process, a pulsed laser deposition (PLD) process, etc. Further, the first electrode 150 may be formed using metal, alloy, a transparent conductive material, etc. The first electrode 150 may be a reflective electrode or a transparent electrode according to the emission type of the display device. For example, when the first electrode 150 includes a transparent conductive material such as indium tin oxide, zinc tin oxide, indium zinc oxide, tin oxide, zinc oxide and/or gallium oxide, the display device may be a bottom emission type. Further, the first electrode 150 may be a single layer structure or a multi layer structure including a metal film, an alloy film and/or a transparent conductive material film.

In some example embodiments, a contact, a pad or a plug may be formed on the drain electrode 127 to fill the first opening of the insulation layer 140. The first electrode 150 may be formed on the insulation layer 140. In this case, the first electrode 150 may be electrically connected to the drain electrode 127 through the contact, the pad or the plug.

Referring to FIG. 12, a pixel defining layer 160 may be formed on the insulation layer 140 in the device region of the display device. In example embodiments, the pixel defining layer 160 may partially cover the first electrode 150 electrically connected to the drain electrode 127. The pixel defining layer 160 may be formed using an organic material and/or an inorganic material. For example, the pixel defining layer 160 may be formed using silicon oxide, silicon nitride, silicon oxynitride, benzocyclobutene-based resin, olefin-based resin, polyimide-based resin, acryl-based resin, polyvinyl-based resin, siloxane-based resin. These may be used alone or in a combination thereof. The pixel defining layer 160 may define a display region generating light in the pixel region.

As described in FIG. 12, an organic light emitting structure 200 may be formed on the pixel defining layer 160 and the first electrode 150. In example embodiments, the organic light emitting structure 200 may be formed by sequentially stacking a hole injection layer 210, a hole transfer layer 220, an organic light emitting layer 230 and an electron transfer layer 240 on the pixel defining layer 160 and the first electrode 150. Each of the hole injection layer 210, the hole transfer layer 220, the organic light emitting layer 230 and the electron transfer layer 240 may be formed by a vacuum evaporation process, an ink-jet printing process, a spin coating process, a laser thermal transfer process, etc.

The hole injection layer 210 may be formed on the first electrode 150 and the pixel defining layer 160. For example, the hole injection layer 210 may be formed using cupper phthalocyanine (CuPc), poly(3,4)-ethylenedioxythiophene (PEDOT), polyaniline (PANI), N,N-dinaphthyl-N,N′-diphenyl benzidine (NPD), etc. The hole transfer layer 220 may be formed on the hole injection layer 210. For example, the hole transfer layer 220 may be formed using N,N-dinaphthyl-N,N′-diphenyl benzidine (NPD), N,N′-bis-(3-methylphenyI)-N,N′-bis-(phenyl)-benzidine (TPD), s-TAD, 4,4′,4″-Tris(N-3-methylphenyl-N-phenyl-amino)-triphenylamine (MTDATA), etc.

The organic light emitting layer 230 may be formed in the display region. The organic light emitting layer 230 may be formed using an organic material or a mixture of an organic material and an inorganic material generating at least one of a red light, a green light, and a blue light. For example, the organic light emitting layer 230 may be formed using tris(8-hydroxyquinolino)aluminum (Alq3), anthracene, distryl, etc. Alternatively, the organic light emitting layer 230 may have a stacked structure including light emitting layers for the red color of light, the green color of light and the blue color of light to generate the white color of light. The electron transfer layer 240 may be formed on the organic light emitting layer 230. For example, the electron transfer layer 240 may be formed using Alq3 (tris(8-hydroxyquinolino)aluminum), PBD, TAZ, spiro-PBD, BAIq, SAIq, etc.

The second electrode 250 may be formed on the electron transfer layer 240. The second electrode 250 may be formed on the electron transfer layer 240 using metal, alloy and/or a transparent conductive material by a sputtering process, a printing process, a spray process, a chemical vapor deposition process, a vacuum evaporation process, an atomic layer deposition process, etc. For example, the second electrode 250 may be formed using aluminum (Al), tungsten (W), copper (Cu), nickel (Ni), chromium (Cr), molybdenum (Mo), titanium (Ti), platinum (Pt), silver (Ag), tantalum (Ta), ruthenium (Ru), alloys thereof, nitrides thereof, indium tin oxide (ITO), indium zinc oxide (IZO), zinc tin oxide (ZTO), zinc oxide (ZnOx), tin oxide (SnOx) gallium oxide (GaOx), etc. These may be used alone or in a combination thereof. The second electrode 250 may be a reflective electrode or a transparent electrode depending on the emission type of the display device.

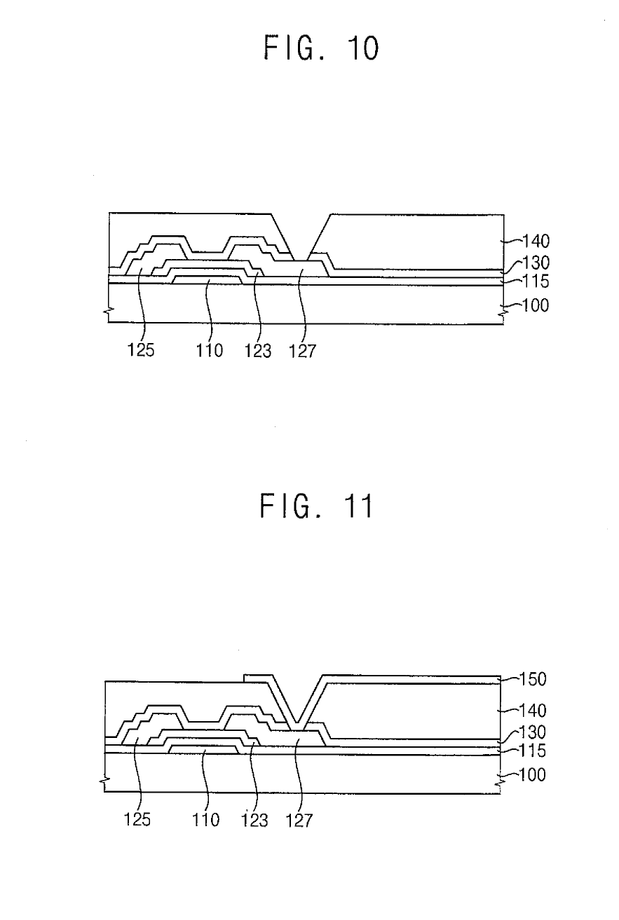

FIG. 13 is a cross sectional view illustrating a display device in accordance with some example embodiments. The display device illustrated in FIG. 13 may have a construction substantially similar to that of the display device taken along a line III-IV illustrated in FIG. 1.

The display device illustrated in FIG. 13 may have a construction substantially the same as or substantially similar to that of the display device described with reference to FIG. 3 except for a gate line 109 and a gate electrode 111.

Referring to FIG. 13, the display device may include a substrate 100, a switching device, a first electrode 150, an organic light emitting structure, a second electrode 250, etc. The switching device may include the gate electrode. 111, gate insulation layer 115, an active pattern 123, a source electrode (not illustrated), a drain electrode (not illustrated), etc. The organic light emitting structure may include a hole injection layer 210, a hole transfer layer 220, an organic light emitting layer, an electron transfer layer 240, etc.

The gate line 109 may extend along a first direction on the substrate 100, and a data line 102 may extend on the substrate 100 along a second direction substantially perpendicular to the first direction.

In example embodiments, the gate line 109 may include a first conductive layer pattern 105 and a second conductive layer pattern 107. The first conductive layer pattern 105 may extend along the second direction on the substrate 100, and the second conductive layer pattern 108 may extend along the first direction substantially perpendicular to the second direction on the first conductive layer pattern 105. The first conductive layer pattern 105 may include amorphous silicon doped highly with impurities. For example, the first conductive layer pattern 105 may include amorphous silicon doped with n-type impurities. The second conductive layer pattern 107 may include metal and/or alloy having a relatively low electrical resistivity such as aluminum (Al), platinum (Pt), silver (Ag), alloys thereof, etc. The second conductive layer pattern 107 may have a relatively large thickness above about 200 nm. The second conductive layer pattern 107 may include a relatively low electrical material, and thus a total resistance of the gate line 109 having the second conductive layer pattern 107 may be reduced.

In example embodiments, a gate electrode 111 may be connected to the first conductive layer pattern 105 of the gate line 109. The gate electrode 111 may include a material substantially the same as or substantially similar to that of the first conductive layer pattern 105. For example, the gate electrode 111 may include amorphous silicon doped highly with impurities. In this case, the gate electrode 111 may be formed integrally with the first conductive layer pattern 105 of the gate line 109.

A gate insulation layer 115, the active pattern 123, a protection layer 130, an insulation layer 140, the first electrode 150, a pixel defining layer 160, the organic light emitting structure and the second electrode 250 may be disposed on the substrate 100 with the gate electrode 111 and the gate line 109. The switching device, the protection layer 130, the insulation layer 140, the first electrode 150, the organic light emitting structure and the second electrode 250 may be substantially the same as or substantially similar to those described with reference to FIGS. 2 and 3, so that detailed descriptions will be omitted.

In the display device according to example embodiments, the gate electrode 111 may have a thickness substantially smaller than that of the gate line 109; and the gate electrode 111 and the first conductive layer pattern 105 of the gate line 109 may include amorphous silicon having a relatively low thermal conductivity and a relatively large heat capacity, so that a heat loss during a crystallization process for forming the active pattern 123 may be reduced or minimized to form uniformly crystallized active pattern 123.

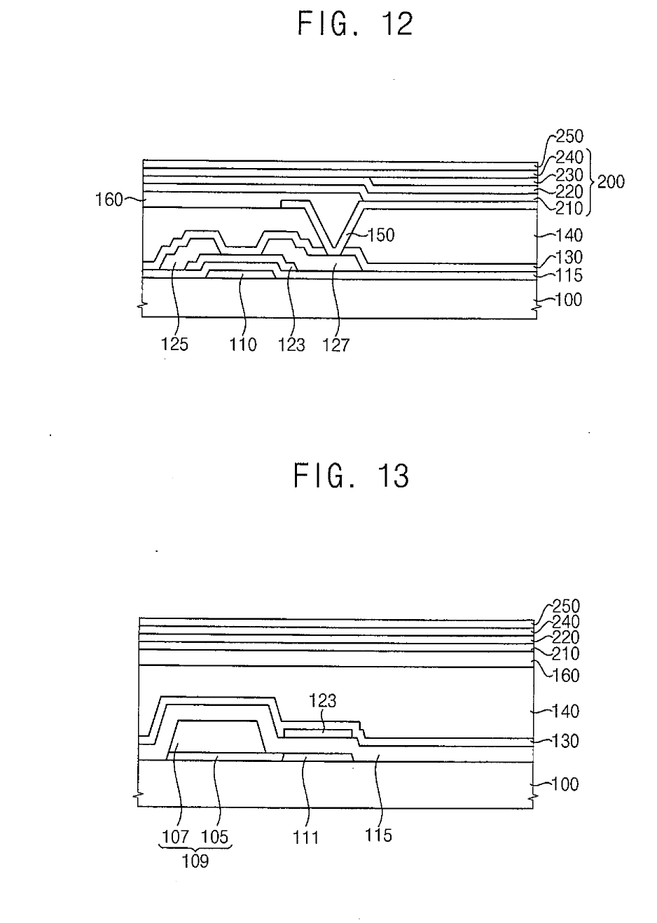

FIGS. 14 to 16 are cross sectional views illustrating a method of manufacturing a display device in accordance with some example embodiments. The method illustrated in FIGS. 14 to 16 may provide a display device having a construction substantially the same as or substantially similar to that of the display device described with reference to FIG. 13. The method of manufacturing the display device illustrated in FIGS. 14 to 16 may be substantially the same as or substantially similar to the method described with reference to FIGS. 4 to 12 except for processes for forming a gate line 109 and a gate electrode 111.

Referring to FIG. 14, the gate line 109 and the gate electrode 111 may be formed on a substrate 100 including a transparent insulating material such as glass, quartz, a transparent resin, a transparent ceramic, etc.

In example embodiments, an amorphous silicon layer (not illustrated) may be formed on the substrate 100 by a chemical vapor deposition process, a plasma enhanced chemical vapor deposition process, a high density plasma-chemical vapor deposition process, etc. In this case, the amorphous silicon layer may include a relatively high concentration of doped impurities. For example, the amorphous silicon layer may include n-type impurities. In this case the impurities may be doped in formation of the amorphous silicon layer in-situ or may be doped after the formation of the amorphous silicon layer. Therefore, the amorphous silicon layer may serve as a conductive layer. The amorphous silicon layer may be patterned to form a first conductive layer pattern 105 and the gate electrode 111. The first conductive layer pattern 105 may extend along a second direction on the substrate 100, and the gate electrode 111 may make contact with the first conductive layer pattern 105. For example, the gate electrode 111 may have a relatively thin thickness below about 50 nm.

A second conductive layer (not illustrated) may be formed on the substrate 100, the first conductive layer pattern 105, and the gate electrode 111 by a sputtering process, a spray process, a chemical vapor deposition process, an atomic layer deposition process, a vacuum evaporation process, a printing process, etc. The second conductive layer may be patterned to form a second conductive layer pattern 107 on the first conductive layer pattern 105. The second conductive layer pattern 107 may extend on the first conductive layer pattern 105 along a first direction substantially perpendicular to the second direction. Accordingly, the gate line 109 having the first and the second conductive layer patterns 105 and 107 may be provided on the substrate 100. For example, the second conductive layer pattern 107 may have a relatively large thickness above about 200 nm, so that a gate resistance may be reduced. The second conductive layer pattern 107 may be formed using metal, alloy, metal nitride, conductive metal oxide, etc. In example embodiments, the second conductive layer pattern 107 may be formed using metal and/or alloy having a relatively low electrical resistivity. For example, the second conductive layer pattern 107 may be formed using aluminum (Al), platinum (Pt), silver (Ag), and/or alloys thereof.

In some example embodiments, before forming the gate line 109 and the gate electrode 111, a buffer layer (not illustrated) may be formed on the substrate 100. The buffer layer may protect or prevent metal atoms and/or impurities from diffusing from the substrate 100. In a crystallization process for forming an active pattern 123, the buffer layer may adjust a heat transfer rate to gain the active pattern 123 having a uniform grain size. Further, the buffer layer may improve a flatness of an upper surface of the substrate 100. The buffer layer may be formed to have a single layer structure or a multi layer structure including at least one silicon compound film.

Referring to FIG. 15, a gate insulation layer 115 and a semiconductor layer 120 may be formed on the substrate 100 with the gate electrode 111 and the gate line 109. Processes for forming the gate insulation layer 115 and the semiconductor layer 120 may be substantially the same as or substantially similar to those described with reference to FIGS. 6 and 7, so that detailed descriptions will be omitted.

The semiconductor layer 120 may be crystallized by irradiating an excimer laser onto the substrate 100 having the semiconductor layer 120. Amorphous silicon in the semiconductor layer 120 may be changed into polysilicon by the crystallization process using the excimer laser. A process for forming the semiconductor layer 120 (including the uniformly crystallized polysilicon) may be substantially the same as or substantially similar to the process described with reference to FIG. 6.

In example embodiments, the gate electrode 111 may have a relatively thin thickness and may include amorphous silicon having a relative low thermal conductivity and a relatively large heat capacity, so that a heat loss through the gate electrode 111 may be reduced or minimized during the crystallization process of the semiconductor layer 120. Therefore, the semiconductor layer 120 may be uniformly and effectively crystallized. Further, the gate line 109 may have a relatively large thickness and may include a metal having a relatively low electrical resistivity, so that increase of a gate resistance due to a thickness reduction in the gate electrode 111 may be compensated.

Referring to FIG. 16, the uniformly crystallized semiconductor layer 120 may be patterned to form the active pattern 123 on the gate insulation layer 115. Processes for forming remaining components of the switching device, a protection layer, an insulation layer, a pixel defining layer, a first electrode, an organic light emitting structure and a second electrode may be substantially the same as or substantially similar to the processes described with reference to FIGS. 8 to 12, so that detailed descriptions will be omitted.

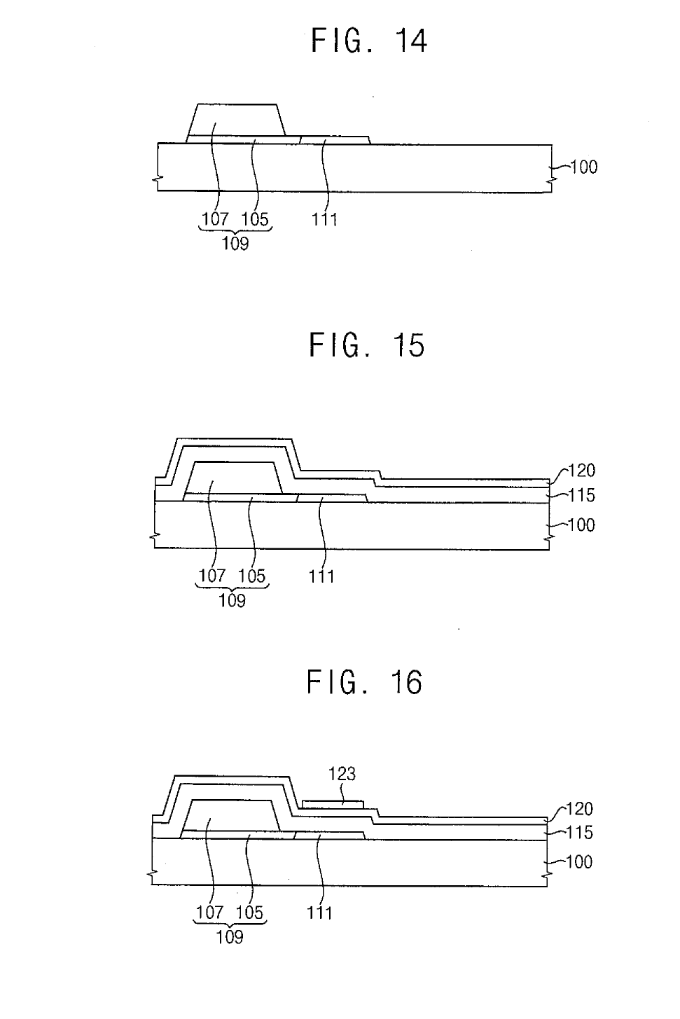

FIG. 17 is a cross sectional view illustrating a method of manufacturing a display device in accordance with some example embodiments. The method of manufacturing a display device illustrated in FIG. 17 may be substantially the same as or substantially similar to the method described with reference to FIGS. 4 to 12 except for a crystallization process of a semiconductor layer 120.

Referring to FIG. 17, a gate line 108, a gate electrode 110, a gate insulation layer 115 and the semiconductor layer 120 may be sequentially formed on a substrate 100. In this case, processes for forming the gate line 108, the gate electrode 110, the gate insulation layer 115 and the semiconductor layer 120 may be substantially the same as or substantially similar to those described with reference to FIGS. 4 to 7, so that detailed descriptions will be omitted.

The semiconductor layer 120 may be crystallized by irradiating an excimer laser onto the substrate 100 having the semiconductor layer 120. Amorphous silicon in the semiconductor layer 120 may be transformed into polysilicon by the crystallization process using the excimer laser. In this case a process for irradiating the excimer laser onto the semiconductor layer 120 may be substantially the same as or substantially similar to the process described with reference to FIG. 6.

In example embodiments, when the excimer laser (indicated using arrow) is irradiated onto an upper surface of the substrate 100, an infrared ray (not illustrated) may be irradiated onto a lower surface of the substrate 100. The substrate 100 and the gate electrode 110 may be heated by the irradiation of the infrared ray. In case temperatures of the substrate 100 and the gate electrode 110 rise by the irradiation of the infrared ray, a temperature difference may be reduced between the semiconductor layer 120 irradiated by the excimer laser and the gate electrode 110. Therefore, the semiconductor layer 120 may include uniformly crystallized polysilicon.

In example embodiments, the gate electrode 110 may have a relatively thin thickness, and the substrate 100 and the gate electrode 110 may be heated by the infrared ray, so that a heat loss through the gate electrode 110 may be reduced or minimized. Therefore, the semiconductor layer 120 may be uniformly and effectively crystallized. Further, the first conductive layer pattern 104 of the gate line 108 may have a relatively large thickness and may include a metal having a relatively low electrical resistivity, so that a growth in a gate resistance due to a thickness reduction in the gate electrode 110 may be compensated.

After forming an active pattern on the gate insulation layer 115 by etching the semiconductor layer 120, a source electrode, a drain electrode, a protection layer, an insulation layer, a first electrode, a pixel defining layer, an organic light emitting structure and a second electrode may be sequentially formed. Processes for forming these elements may be substantially the same as or substantially similar to the processes described with reference to FIGS. 8 to 12, so that detailed descriptions will be omitted.

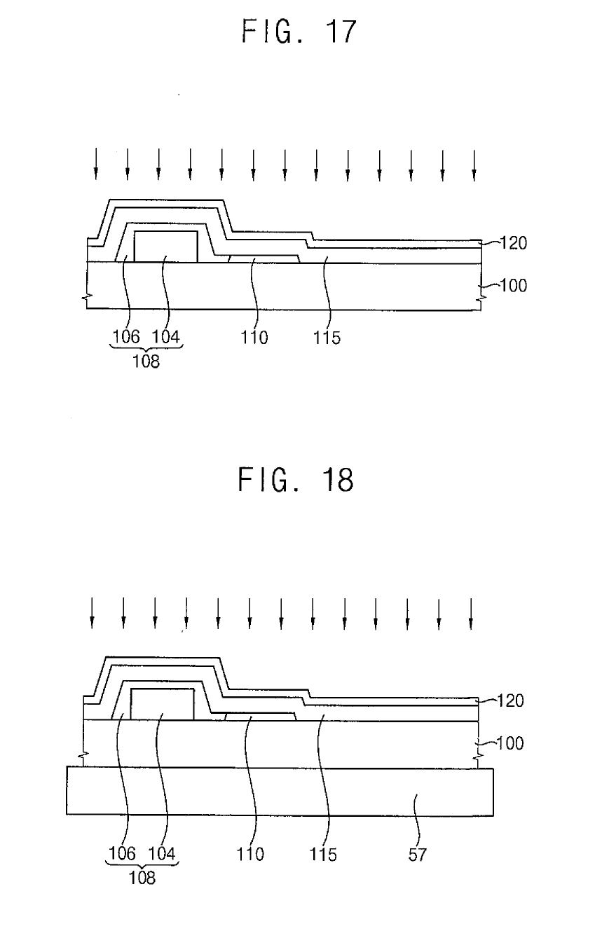

FIG. 18 is a cross sectional view illustrating a method of manufacturing a display device in accordance with some example embodiments. The method of manufacturing the display device illustrated in FIG. 18 may be substantially the same as or substantially similar to the method described with reference to FIGS. 4 to 12 except for a crystallization process of a semiconductor layer 120.

Referring to FIG. 18, a gate line 108, a gate electrode 110, a gate insulation layer 115 and the semiconductor layer 120 may be sequentially formed on a substrate 100. In this case, processes for forming the gate line 108, the gate electrode 110, the gate insulation layer 115 and semiconductor layer 120 may be substantially the same as or substantially similar to those described with reference to FIGS. 4 to 7.

After disposing the substrate 100 having the semiconductor layer 120 on a chuck 57, the semiconductor layer 120 may be crystallized by irradiating an excimer laser onto the semiconductor layer 120. That is, when the excimer laser is irradiated onto the semiconductor layer 120, the substrate 100 may be disposed on the chuck 57 capable of controlling temperature. The substrate 100 and the gate electrode 110 may be heated by the chuck temperature. When temperatures of the substrate 100 and the gate electrode 110 are increased by the chuck 57, a temperature difference may be reduced between the semiconductor layer 120 irradiated by the excimer laser and the gate electrode 110. Therefore, the semiconductor layer 120 may include uniformly crystallized polysilicon.

In example embodiments, the gate electrode 110 may have a relatively thin thickness, and the substrate 100 and the gate electrode 110 may be heated by the chuck 57 capable of controlling temperature, so that a heat loss through the gate electrode 110 may be reduced or minimized. Therefore, the semiconductor layer 120 on the gate electrode 110 may be uniformly and effectively crystallized. Further, the gate line 108 may have a relatively large thickness and may include a metal having a relatively low electrical resistivity, so that a growth in a gate resistance due to a thickness reduction in the gate electrode 110 may be compensated.

After forming an active pattern (not illustrated) on the gate insulation layer 115 by patterning the semiconductor layer 120, other elements of the display device may be sequentially formed. Processes for forming the elements may be substantially the same as or substantially similar to the processes described with reference to FIGS. 8 to 12.

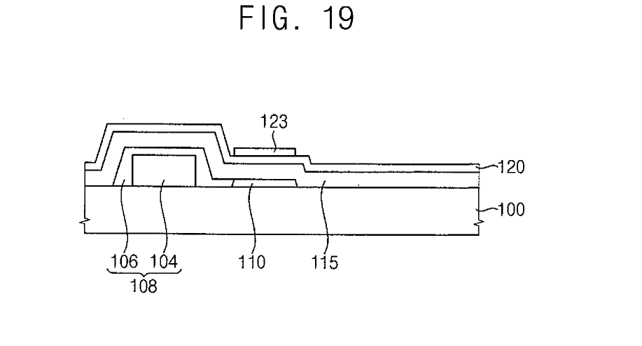

FIG. 19 is a cross sectional view illustrating a method of manufacturing a display device in accordance with some example embodiments. The method of manufacturing the display device illustrated in FIG. 19 may be substantially the same as or substantially similar to the method described with reference to FIGS. 4 to 12 except for a crystallization process of a semiconductor layer 120.

Referring to FIG. 19, a gate line 108, a gate electrode 110, a gate insulation layer 115 and the semiconductor layer 120 may be sequentially formed on a substrate 100. In this case, processes for forming the gate line 108, the gate electrode 110, the gate insulation layer 115 and semiconductor layer 120 may be substantially the same as or substantially similar to those described with reference to FIGS. 4 to 7.

In example embodiments, when the excimer laser (indicated using arrows) is irradiated onto the semiconductor layer 120 to crystallize the semiconductor layer 120, a current may be applied to the gate electrode 110. In this case a process for irradiating the excimer laser onto the semiconductor layer 120 may be substantially the same as or substantially similar to the process described with reference to FIG. 6. An electrical resistance heat may be generated by the applied current, so that the gate electrode 110 and adjacent substrate 100 may be heated. When temperatures of the substrate 100 and the gate electrode 110 are increased by the electrical resistance heat, a temperature difference may be reduced between the semiconductor layer 120 irradiated by the excimer laser and the gate electrode 110. Therefore, the semiconductor layer 120 may include a uniformly crystallized polysilicon.

In example embodiments, the gate electrode 110 may have a relatively thin thickness, and the gate electrode 110 may be heated by the electrical resistance heat, so that a heat loss through the gate electrode 110 may be reduced or minimized. Therefore, the semiconductor layer 120 on the gate electrode 110 may be uniformly and effectively crystallized.

After forming an active pattern 123 on the gate insulation layer 115 by patterning the semiconductor layer 120, other elements of the display device may be sequentially formed. Processes for forming the elements may be substantially the same as or substantially similar to the processes described with reference to FIGS. 8 to 12, so that detail description will be omitted.

According to example embodiments, a display device may include a switching device having a uniformly crystallized active pattern. Electrical characteristics of the switching device may be improved, so that the display device may have increased display speed and improved display quality. The display device may be of various suitable emission types such as a bottom emission type, a top emission type or a both-sides emission type, and may be widely employed in various suitable electronic and electric apparatuses such as televisions, mobile communication apparatuses, monitors, MP3 players or portable display apparatuses.

The foregoing is illustrative of example embodiments, and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope of example embodiments as defined in the claims. In the claims, means-plus-function clauses are intended to cover the structures described herein as performing the recited function, and not only structural equivalents, but also equivalent structures. Therefore, it is to be understood that the foregoing is illustrative of example embodiments and is not to be construed as limited to the specific embodiments disclosed, and that modifications to the disclosed example embodiments, as well as other example embodiments, are intended to be included within the scope of the appended claims. The invention is defined by the following claims, with equivalents of the claims to be included therein.

What is claimed is:

1. A display device comprising:
a gate line comprising a first conductive layer pattern and a second conductive layer pattern, the first conductive layer pattern extending along a first direction, the second conductive layer pattern extending along a second direction;
a switching device connected to the gate line;
a first electrode electrically connected to the switching device;
an organic light emitting structure on the first electrode; and
a second electrode on the organic light emitting structure.

2. The display device of claim 1, wherein the second conductive layer pattern covers the first conductive layer pattern, and a gate electrode of the switching device is connected to the second conductive layer pattern.

3. The display device of claim 2, wherein the first conductive layer pattern comprises a material selected from the group consisting of aluminum (Al), silver (Ag), platinum (Pt), and alloys thereof.

4. The display device of claim 2, wherein the second conductive layer pattern comprises a material selected from the group consisting of molybdenum (Mo), titanium (Ti), chromium (Cr), tantalum (Ta) and alloys thereof.

5. The display device of claim 2, wherein the gate electrode is formed together with the second conductive layer pattern.

6. The display device of claim 2, wherein the gate electrode has a thickness identical to that of the second conductive layer pattern.

7. The display device of claim 6, wherein the first conductive layer pattern has a thickness larger than that of the gate electrode or that of the second conductive layer pattern.

8. The display device of claim 1, wherein the second conductive layer pattern is disposed on the first conductive layer pattern, and a gate electrode of the switching device is connected to the first conductive layer pattern.

9. The display device of claim 8, wherein the gate electrode is formed together with the first conductive layer pattern.

10. The display device of claim 9, wherein each of the first conductive layer pattern and the gate electrode comprises silicon doped with impurities.

11. The display device of claim 8, wherein the second conductive layer pattern comprises a material selected from the group consisting of aluminum (Al), silver (Ag), platinum (Pt) and alloys thereof.

12. The display device of claim 8, wherein the gate electrode has a thickness identical to that of the second conductive layer pattern, and the first conductive layer pattern has a thickness larger than that of the gate electrode or that of the second conductive layer pattern.

13. A method of manufacturing a display device, the method comprising:
forming a gate line on a substrate, the gate line comprising a first conductive layer pattern extending along a first direction and a second conductive layer pattern extending along a second direction;
forming a switching device comprising a gate electrode connected to the gate line;
forming a first electrode electrically connected to the switching device;
forming an organic light emitting structure on the first electrode; and
forming a second electrode on the organic light emitting structure.

14. The method of claim 13, wherein the forming of the gate line comprises:
forming the first conductive layer pattern on the substrate; and
forming the second conductive layer pattern to enclose the first conductive layer pattern.

15. The method of claim 14, wherein the second conductive layer pattern and the gate electrode are formed concurrently.

16. The method of claim 13, wherein the forming of the gate line comprises:
forming the first conductive layer pattern on the substrate; and
forming the second conductive layer pattern on the first conductive layer pattern.

17. The method of claim 16, wherein the first conductive layer pattern and the gate electrode are formed concurrently.

18. The method of claim 13, wherein the forming of the switching device comprises:
forming a gate insulation layer on the substrate to cover the gate electrode;
forming a semiconductor layer comprising amorphous silicon on the gate insulation layer; and
crystallizing the semiconductor layer using an excimer laser.

19. The method of claim 18, further comprising heating the substrate and the gate electrode to crystallize the semiconductor layer.

20. The method of claim 19, wherein the heating of the substrate and the gate electrode comprises irradiating an infrared ray onto the substrate.

21. The method of claim 19, wherein the heating of the substrate and the gate electrode comprises disposing the substrate on a chuck capable of controlling temperature.

22. The method of claim 19, wherein the heating of the substrate and the gate electrode comprises applying a current to the gate electrode.
